(19) United States
(12) Patent Application Publication
(10) Pub. No.: US 2022/0338340 A1
(43) Pub. Date: Oct. 20, 2022

(54) HOOK AND LOOP ATTACHMENT FOR RADIATION SHIELD AND HEAT SINK

(71) Applicant: Intel Corporation, Santa Clara, CA (US)

(72) Inventors: Juha Tapani Paavola, Hillsboro, OR (US); Sami Markus Heinisuo, Portland, OR (US); Kari Pekka Johannes Mansukoski, Hillsboro, OR (US)

(73) Assignee: Intel Corporation, Santa Clara, CA (US)

(21) Appl. No.: 17/856,791

(22) Filed: Jul. 1, 2022

(51) Int. Cl. H05K 1/02; H05K 9/00; H05K 7/20

(52) U.S. Cl. CPC H05K 1/0203; H05K 9/0024; H05K 7/2039

(57) ABSTRACT

Particular embodiments described herein provide for an electronic device can include a support structure, a radiation source on the support structure, a radiation shield around the radiation source, and a hook and loop radiation shield securing mechanism to removably secure the radiation shield to the support structure, where the hook and loop radiation shield securing mechanism includes a hook portion with a plurality of hooks and a loop portion that includes a plurality of loops, where an angle of a retention hook for each of the plurality of hooks is less than about eighty degrees.

### TECHNICAL FIELD

This disclosure relates in general to the field of computing, and more particularly, to a hook and loop attachment for a radiation shield and a heat sink.

### BACKGROUND

Emerging trends in systems place increasing performance demands on the system. One way to attempt to improve performance and function is to increase the density of the devices and systems and pack more computing elements into the devices and systems. The increasing performance demands can create a relatively crowded system as more and more components are located in close proximity to each and can cause radiating noise level increases in the system. More specifically, the increase in computing elements often causes elevated noise levels in systems. Electromagnetic interference (EMI) and radio-frequency interference (RFI) affect almost every electronic device, especially mobile compute devices. In addition, some electrical components are both a source of electromagnetic and radio-frequency radiation and are susceptible to EMI/RFI from adjacent sources. The radiating noise level can cause a reduction in device performance, a reduction in the lifetime of a device, and/or delays in data throughput.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIGS. 1A and 1B are simplified block diagrams of a system to enable a hook and loop attachment for a radiation shield and a heat sink, in accordance with an embodiment of the present disclosure;

FIG. 2 illustrates example details of a portion of a system to enable a hook and loop attachment for a radiation shield and a heat sink, in accordance with an embodiment of the present disclosure;

FIG. 3 is a simplified block diagram illustrating example details of a portion of a system to enable a hook and loop attachment for a radiation shield and a heat sink, in accordance with an embodiment of the present disclosure;

FIG. 4 is a simplified block diagram illustrating example details of a portion of a system to enable a hook and loop attachment for a radiation shield and a heat sink, in accordance with an embodiment of the present disclosure;

FIG. 5 is a simplified table illustrating example details of a system to enable a hook and loop attachment for a radiation shield and a heat sink, in accordance with an embodiment of the present disclosure;

FIG. 6 is a simplified flowchart illustrating potential operations that may be associated with the system in accordance with an embodiment of the present disclosure; and

FIG. 7 is a block diagram illustrating example devices that include a hook and loop attachment for a radiation shield and a heat sink, in accordance with an embodiment of the present disclosure.

The FIGURES of the drawings are not necessarily drawn to scale, as their dimensions can be varied considerably without departing from the scope of the present disclosure.

### DETAILED DESCRIPTION

The following detailed description sets forth examples of apparatuses, methods, and systems relating to enabling a hook and loop attachment for a radiation shield and a heat sink. Features such as structure(s), function(s), and/or characteristic(s), for example, are described with reference to one embodiment as a matter of convenience; various embodiments may be implemented with any suitable one or more of the described features.

### Overview

In an example, a hook and loop attachment for a radiation shield and a heat sink can be used to secure the radiation shield and/or a heat sink to a support structure (e.g., a printed circuit board). The radiation shield and/or heat sink can be over one or more radiation sources on the support structure. The one or more radiation sources can be a heat source (e.g., a processor or some other heat source that also generates radiation, particularly electromagnetic radiation and/or radio-frequency radiation). The radiation shield can include a lid portion and radiation shield wall portion. The radiation shield wall portion can be coupled to a hook portion of the hook and loop attachment. A loop portion of the hook and loop attachment can be coupled to the support structure and the ground plane of the support structure. When the hook portion of the hook and loop attachment is coupled to the loop portion of the hook and loop attachment, the radiation shield is grounded. The radiation shield can be a heat sink and more particularly a vapor chamber or cold plate. The hook and loop attachment can secure the radiation shield and/or heat sink to the support structure in the X, Y, and Z planes. The term “X plane,” refers to the plane along the “X” axis of an (x, y, z) coordinate axis or cartesian coordinate system, the term “Y plane,” refers to the plane along the “Y” axis of the (x, y, z) coordinate axis or cartesian coordinate system, and the term “Z plane,” refers to the plane along the “Z” axis of the (x, y, z) coordinate axis or cartesian coordinate system.

In an example, an electronic device can include a support structure, a radiation source on the support structure, a radiation shield around the radiation source, and a hook and loop radiation shield securing mechanism to removably secure the radiation shield to the support structure. The hook and loop radiation shield securing mechanism can include a hook portion with a plurality of hooks and a loop portion that includes a plurality of loops, where an angle of a retention hook for each of the plurality of hooks is less than about eighty degrees. In some examples, the angle of the retention hook for each of the plurality of hooks is less than about forty degrees. Also, the hook and loop radiation shield securing mechanism can be grounded to a ground plane of the support structure. In some examples, the radiation shield is a flexible heat spreader.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

The terms “over,” “under,” “below,” “between,” and “on” as used herein refer to a relative position of one layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “directly on” a second layer is in direct contact with that second layer. Similarly, unless explicitly stated otherwise, one feature disposed between two features may be in direct contact with the adjacent features or may have one or more intervening layers.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example. The term “about” indicates a tolerance of twenty percent (20%). For example, about one (1) millimeter (mm) would include one (1) mm and ±0.2 mm from one (1) mm. Similarly, terms indicating orientation of various elements, for example, “coplanar,” “perpendicular,” “orthogonal,” “parallel,” or any other angle between the elements generally refer to being within +/− 5-20% of a target value based on the context of a particular value as described herein or as known in the art.

### Example Hook and Loop Attachment for a Radiation Shield and a Heat Sink

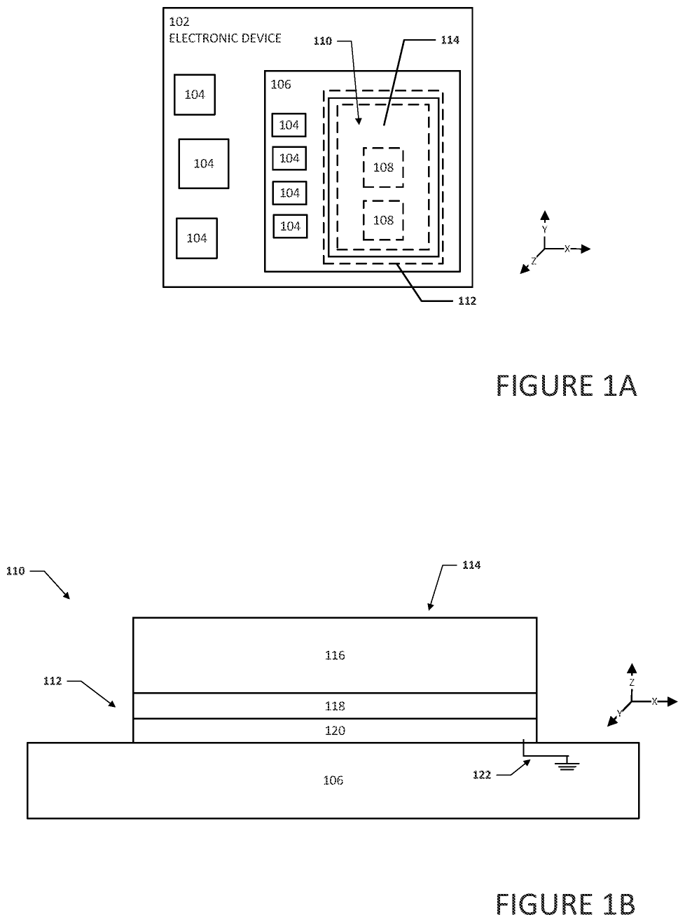

FIGS. 1A and 1B are simplified block diagrams of an electronic device 102 configured with a hook and loop attachment for a radiation shield and a heat sink, in accordance with an embodiment of the present disclosure. In an example, the electronic device 102 can include one or more electronics 104 and a support structure 106. The support structure 106 can include at least one of the one or more electronics 104, one or more radiation sources 108, a radiation shield 110, a hook and loop radiation shield securing mechanism 112, and a ground 122 (shown in FIG. 1B). The radiation shield 110 can include a lid portion 114 and a radiation shield wall portion 116 (shown in FIG. 1B). In some examples, the lid portion 114 and the radiation shield wall portion 116 are separate pieces of material, elements, components, etc. More specifically, the lid portion 114 may be a first electrically conductive material (e.g., an electrically conductive cold plate) and the radiation shield wall portion 116 may be a second electrically conductive material (e.g., an electrically conductive spacer or raiser to accommodate the height of the one or more radiation sources 108). Each of the one or more electronics 104 can be a device or group of devices available to assist in the operation or function of the electronic device.

In an example, the support structure 106 can be a substrate and more particularly, a printed circuit board (PCB). The ground 122 can be a ground plane of the PCB. The one or more radiation sources 108 can be on or over the support structure 106 and the radiation shield 110 can be over the one or more radiation sources 108. The one or more radiation sources 108 can be a heat source (e.g., a processor or some other heat source that also generates radiation, particularly electromagnetic radiation and/or radio-frequency radiation). The radiation shield 110 can be a heat sink and more particularly a vapor chamber or cold plate. As used herein, the term “heat sink” includes a component or components that help to move heat away from the one or more heat sources (e.g., the radiation source 108).

The hook and loop radiation shield securing mechanism 112 can be between the support structure 106 and the radiation shield wall portion 116 of the radiation shield 110. More specifically, the hook and loop radiation shield securing mechanism 112 can include a loop portion 120 and a hook portion 118. The loop portion 120 can be secured to the support structure 106 and the hook portion 118 can be secured to the radiation shield wall portion 116 of the radiation shield 110. The loop portion 120 can be secured to the support structure 106 using a solder, adhesive, tape, a weld, a mechanical fastener (e.g., screw, bolt, rivet, etc.), or some other type of fastener or coupling means that can secure the loop portion 120 to the support structure 106. The hook portion 118 can be secured to the radiation shield wall portion 116 using a solder, adhesive, tape, a weld, a mechanical fastener (e.g., screw, bolt, rivet, etc.), or some other type of fastener or coupling means that can secure the hook portion 118 to the radiation shield wall portion 116. In some examples, the hook portion 118 is secured to the support structure 106 and the loop portion 120 is secured to the radiation shield wall portion 116 of the radiation shield 110.

The hook and loop radiation shield securing mechanism 112 can be coupled to the ground 122 so that hook and loop radiation shield securing mechanism 112 and the radiation shield 110 are grounded. The lid portion 114 and the radiation shield wall portion 116 define a cavity inside the radiation shield 110 that can cover and house the one or more radiation sources 108 and can help provide a shielding mechanism for the one or more radiation sources 108. The hook and loop radiation shield securing mechanism 112 can secure the radiation shield 110 to the support structure 106 without creating holes in support structure 106.

The lid portion 114 and the radiation shield wall portion 116 of the radiation shield 110 may be the same single piece of material where the lid portion 114 is the material on the edge or side that is relatively parallel to the support structure 106 and the radiation shield wall portion 116 is the material on the edges or sides that are relative perpendicular to the support structure 106. The lid portion 114 and the radiation shield wall portion 116 can be comprised of a conducive material and can include stainless steel, copper, an alloy such as nickel copper, or some material that is conductive and rigid, semi-rigid, or flexible. The lid portion 114 and the radiation shield wall portion 116 can help contain or mitigate the radiation from the one or more radiation sources 108 from extending past the radiation shield 110 or at least partially contain or mitigate the radiation from the one or more radiation sources 108 from extending past the radiation shield 110. In an example, the lid portion 114 and the radiation shield wall portion 116 may be two separate components and may be comprised of the same material or the lid portion 114 may be comprised of a different material then the radiation shield wall portion 116. For example, the lid portion 114 may be comprised of a thermally and electrically conductive material and the radiation shield wall portion 116 may only be comprised of an electrically conductive material and not a thermally conductive material or of an electrically conductive material that is not as thermally conductive as the lid portion 114.

The radiation from the one or more radiation sources 108 may be electromagnetic radiation, internal and external Wi-Fi and cellular radio-frequency radiation, high speed input/output (I/O) trace/connector digital noise radiation, switching voltage regulator radiation, or some other type of radiation that can have an undesirable effect on one or more components of an electronic device. For example, electromagnetic interference (EMI) and radio-frequency interference (RFI) affect almost every electronic device, especially mobile compute devices. System on a chip (SoC) packages are both a source of electromagnetic radiation and radio-frequency radiation and are susceptible to EMI/RFI from adjacent sources. For example, when a smartphone is placed on or near a keyboard of a laptop, performance of the laptop is often impacted (e.g., laptop screen flicker, CPU hang, reboot of the system, etc.). The term “radiation” includes electromagnetic radiation, radio-frequency radiation, and other similar radiation that can cause an undesirable effect on one or more components of an electronic device.

It is to be understood that other embodiments may be utilized and structural changes may be made without departing from the scope of the present disclosure. Substantial flexibility is provided in that any suitable arrangements and configuration may be provided without departing from the teachings of the present disclosure.

For purposes of illustrating certain example techniques, the following foundational information may be viewed as a basis from which the present disclosure may be properly explained. End users have more media and communications choices than ever before. A number of prominent technological trends are currently afoot (e.g., more computing elements, more online video services, more Internet traffic, more complex processing, etc.), and these trends are changing the expected performance of devices as devices and systems are expected to increase performance and function. One way to increase performance and function is to increase the density of the devices and systems and pack more computing elements into the devices and systems. However, the increase in computing elements causes an increase in the EMI and RFI. EMI and RFI affect almost every electronic device, especially mobile compute devices. In addition, SoC packages are both a source of electromagnetic and radio-frequency radiation and are susceptible to EMI/RFI from adjacent sources.

Die and package radiation have been identified as RFI risk factors. In addition, radio frequency signals from internal radios and external smartphones in proximity to personal computers have interfered with the SoCs and caused basic functionality issues, including display flickering and system hang/reboot. Some SoC designs introduce disaggregation and multichip package (MCP) using an embedded multi-die interconnect bridge (EMIB) which can increase both RFI and immunity risk. Also, scalable package-level shielding techniques (simultaneously shielding both the package and the dies) are required for some Internet of Things (IoT) devices, data centers, SoCs, and seven (7)/ten (10) nm disaggregated systems.

In some systems, the package layer-count increases to provide a package surface shielding with a ground layer at the expense of package cost and system Z height. However, the package surface shielding can be insufficient because of multiple-die radiation. In addition, package surface shielding with an additional ground layer reduces radio frequency noise radiation/coupling but at the expense of package cost and Z height increases. In other systems, a conductive coating may be used. However, a conductive coating, such as metal sputtering, is considered to be prohibitively expensive and is an uncertified manufacturing process for SoC applications and high-volume manufacturing.

In some systems, an on-board shield may be used to implement a Faraday cage with a motherboard and PCB ground contacts. While on-board shielding is relatively common, it requires good ground stitching between the Faraday cage and motherboard and PCB ground contacts. In general, about 2.5 to about five (5) mm ground stitching space (about λ/20 to about λ/10) is required to provide good shielding effectiveness up to about five (5) to about six (6) GHz WiFi channels. This requirement is almost impossible to meet for Type-3 PCBs and for compact size shielding solutions, especially for SoCs with high-density interconnects. Increasing the size of shielding for its placement around less dense PCB areas can cause mechanical warp, height increase, and thermal contact issues. The shielding effectiveness significantly relies on PCB designs and technologies (e.g., Type-3 PCB vs. Type-4 PCB) and the on-board shielding solutions are applicable only for Type-4 PCBs, which are higher in cost than Type-3 and are used only for a small number of premium PCs. High volume PCs are designed with Type-3 PCBs.

Some current radiation shield designs are often unable to resolve the effectiveness of shielding and meet the cost target. For example, a relatively high cost is typically associated with most two-piece metal radiation shields (lid and frame) and surface mount technology issues can arise due to frame warpage. Also, some radiation shields with a lid and clip design have a reduced shied effectiveness due to the seam or gap in between the clips where the radiation shield does not make contact with the PCB. In addition, with some lid and clip designs, damage to the radiation shield can cause high downtime for repairing due to the many clips causing low serviceability, especially if one or more of the clips needs to be replaced.

With a growing trend of thin and light devices, there is an industry driven need to have a compact core area of the motherboard (SOC area) that allows for flexibility in placing and routing components. One of the main tradeoffs that is seen during routing and component placement in the core area is the requirements of the location of the drill holes in the mother board. Typically, the workaround solution with the constraint of the holes in the mother board yields in either increase in trace lengths of high-speed signals or ends up placing components in areas that are not intended for component placement.

In addition, the requirement of increased performance in thin systems possess challenge on designing thermal solutions that occupy a relatively small footprint on the support structure and still produce the necessary load to achieve a thin and uniform layer of TIM and uniform pressure on the heat source to allow for desired thermal performance. Insufficient pressure or loading on the heat source limits the choice of TIM that may be used in the system. One current way thermal performance targets are typically achieved is by decreasing the thermal resistance between the heat source and the cold plate. The thermal resistance between the heat source and the cold plate is typically decreased by either increasing the load on the heat source from the cold plate or by changing to a different TIM that exhibits reduced thermal resistance for the same pressure, which may be nearing a point of diminishing returns for state-of-the-art grease TIMs, and/or can be cost-prohibitive for high volume manufacture for fundamentally new classes of TIMs (e.g., liquid metal).

Most typical thermal solution designs involve using a heat pipe and copper heat spreader in combination with attachment springs to try and obtain a desired loading. The attachment springs are usually are made of steel which deflect a defined distance to provide the desired load on the heat source and help to create a uniform thickness of TIM. The heat pipe, copper spreader, and attachment spring are usually stacked in layers. Some common typical thermal solutions (cold plate and heat pipe) are attached by a four-point attachment system that includes four leaf springs and four screws to create a desired amount of pressure on the cold plate and on the TIM and the heat source. Typically, the leaf springs extend relatively far away from the cold plate to generate a bending moment to create the desired pressure on the cold plate, TIM, and heat source. In addition, the leaf springs are attached to the PCB using four holes in the PCB and the four holes prevent trace routing around the \ hole area. The four-leaf springs and screws create keep out zones on the PCB and limit where other components of the electronic device can be located on the PCB and the leaf springs and four screws take up valuable space on the PCB. In addition, there can be a relatively higher costs due to the high number of attachment points.

Some systems use a three-point attachment system, because the reduction of one hole will decrease the keep out zone size and allow for relatively easier routing in PCB layers because in a three-point attachment system, one hole is removed as compared to the four-point attachment system that requires four holes in the PCB. However, the three-point attachment system typically does not produce a smooth pressure or an even distribution of the pressure from the cold plate as compared to the four-point attachment system. Also, in a three-point attachment system, the leaf arm is longer on one side and that can cause cold plate bending. Further, with a three-point attachment system, the cold plate is not typically saddled properly on the TIM and heat source and does not create a desired uniform pressure on the TIM and heat source. In addition, the screw locations for most three-point attachment systems are relatively far away from the cold plate and this can generate a bending moment that deflects the cold plate and decreases the thermal performance of the cold plate. To further reduce the amount of holes in the PCB, some systems use a two-point attachment. However, as with the three-point attachment system, with some current two-point attachment systems, the cold plate can easily tilt and put pressure on one side of the TIM and heat source and almost none on the other side of the TIM and heat source.

There is also a strong need in “always connected” (4G/5G radios adoption) thin and light devices and bezel less laptops to place the antenna in the base. The antenna in the base leads to more challenges/complexity in RFI as the noise sources such as CPU, GPU, memory etc. are placed very close to the antenna. In such scenarios, shielding becomes a critical requirement to prevent RFI. Platform on-board shield can reduce platform noise radiation for interfaces such as memory subsystem however, poor ground contact design and electrical openings in the on-board shield can reduce the shielding effectiveness.

Some EMI shields use an edge snap connection however, often an edge snap connection will cause an alignment problem. For example, if the EMI shield (e.g., typically stiff, 0.50 mm copper) is attached at the edges with traditional locking snaps, those snaps will locate the thermal solution (including heat pipes) firmly. This can cause a misalignment issue for heat exchangers because if the angle deviation is off by just one (1) degree, a misalignment of +/− three (3) millimeters can occur at the heat exchanger. Another risk is Z-direction loading from contact snaps and the vertical load can cause easily biased die pressure distribution. Some current systems use conductive foam at the shield edges however, conductive foam needs quite high compression and can often raise the shield edge so that the die pressure is biased. Some current systems use copper or graphite taper sealing. However, tape sealing is time consuming to assemble at high volume manufacturing production lines and has EMI leak risk in the long run. Some current systems use a contact spring connection at the shield edges. However, grounding springs at the edge will also generate edge load which will deflect the shield and cause biased die pressure and if the angle deviation is off by just one (1) degree, a misalignment of +/− three (3) millimeters can occur at the heat exchanger. What is needed is a radiation shield and/or heat exchanger that can be coupled to a substrate without creating holes in the PCB.

A hook and loop attachment for a radiation shield and a heat sink, as outlined in FIGS. 1A and 1B, can resolve these issues (and others). In an example, a radiation shield (e.g., the radiation shield 110) can include a lid portion (e.g., the lid portion 114) and a radiation shield wall portion (e.g., the radiation shield wall portion 116). The radiation shield can be over one or more radiation sources (e.g., the one or more radiation sources 108) on a support structure (e.g., the support structure 106). The one or more radiation sources can be a heat source (e.g., a processor or some other heat source that also generates radiation, particularly electromagnetic radiation and/or radio-frequency radiation). The radiation shield can be a heat sink and more particularly a vapor chamber or cold plate. As used herein, the term “heat sink” includes a component or components that help to move heat away from the one or more radiation sources. The radiation shield can be secured to the support structure using a hook and loop radiation shield securing mechanism (e.g., the hook and loop radiation shield securing mechanism 112).

The hook and loop radiation shield securing mechanism can include a loop portion (e.g., the loop portion 120) and a hook portion (e.g., the hook portion 118). The loop portion can be secured to the support structure and the hook portion can be secured to the radiation shield wall portion of the radiation shield. The loop portion can be secured to the support structure using solder, adhesive, tape, a weld, a mechanical fastener (e.g., screw, bolt, rivet, etc.), or some other type of fastener or coupling means that can secure the loop portion to the support structure. The hook portion can be secured to the radiation shield wall portion using a solder, adhesive, tape, a weld, a mechanical fastener (e.g., screw, bolt, rivet, etc.), or some other type of fastener or coupling means that can secure the hook portion to the radiation shield wall portion of the radiation shield. In some examples, the hook portion is secured to the support structure and the loop portion is secured to the radiation shield wall portion of the radiation shield.

The hook and loop radiation shield securing mechanism can be coupled to a ground of the support structure (e.g., the ground 122) so that the radiation shield is grounded. The lid portion and the radiation shield wall portion define a cavity inside the radiation shield that can cover and house the one or more radiation sources and can help provide a shielding mechanism for the one or more radiation sources. The hook and loop radiation shield securing mechanism can secure the radiation shield to the support structure without creating holes in support structure.

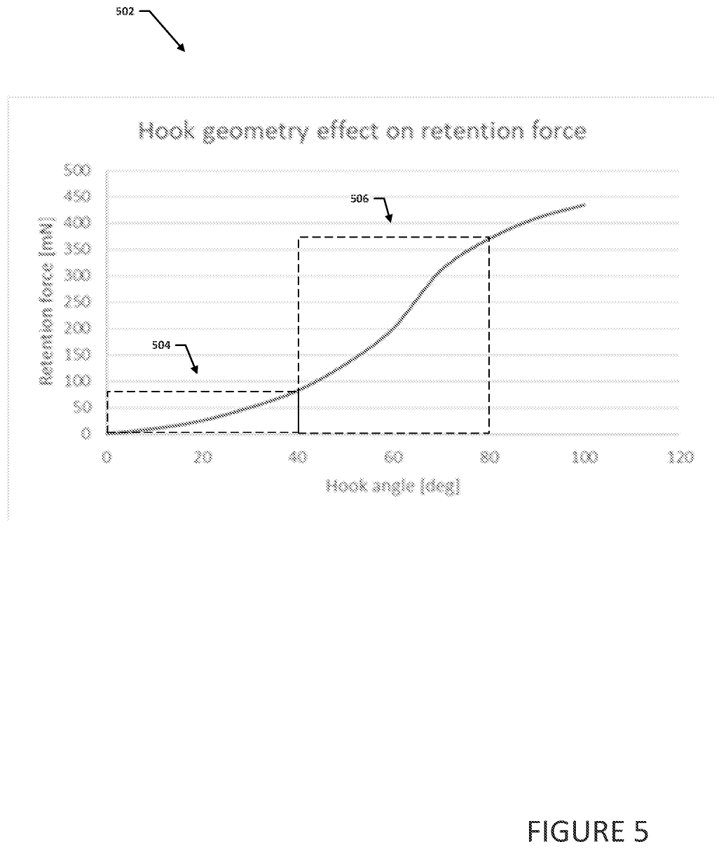

In some examples, for a combined relatively wide thermal solution and radiation shield, the hook and loop radiation shield securing mechanism can apply a low or almost zero vertical Z-load and about zero horizontal X-Y-loads to help prevent warpage and damage to the relatively wide thermal solution and radiation shield. Also, the hook and loop radiation shield securing mechanism can be used with a flexible heat spreader and/or thermally conductive elastic material coated with radiation shielding film. In other examples, a hook and loop radiation shield securing mechanism with a relatively strong retention force (e.g., see FIG. 5) can be used to hold an applied load on the one or more radiation sources. Using the hook and loop radiation shield securing mechanism, the radiation shield can be relatively easy to detach and re-attach without any special tools, permanent deformation, or failure risk.

In addition, the radiation shield can be attached to the support structure by the hook and loop radiation shield securing mechanism without requiring any holes in the support structure and it does not limit the trace routing design. More specifically, the hook and loop attachment for the radiation shield can allow for a more compact core area on the support structure as there are no holes required in the support structure. Because there are no holes in the support structure, space on the support structure can be saved and the routing of trace lines on the support structure can be easier than if the support structure included holes. The seamless (no gap) connection between the radiation shield and the support structure helps to provide a shield against the effects of electromagnetic waves. More specifically, the radiation shield can provide attenuations of 80 dB for a lower frequency of 2.45 GHz and at least 30 dB attenuation for a higher frequency of 6.5 GHz.

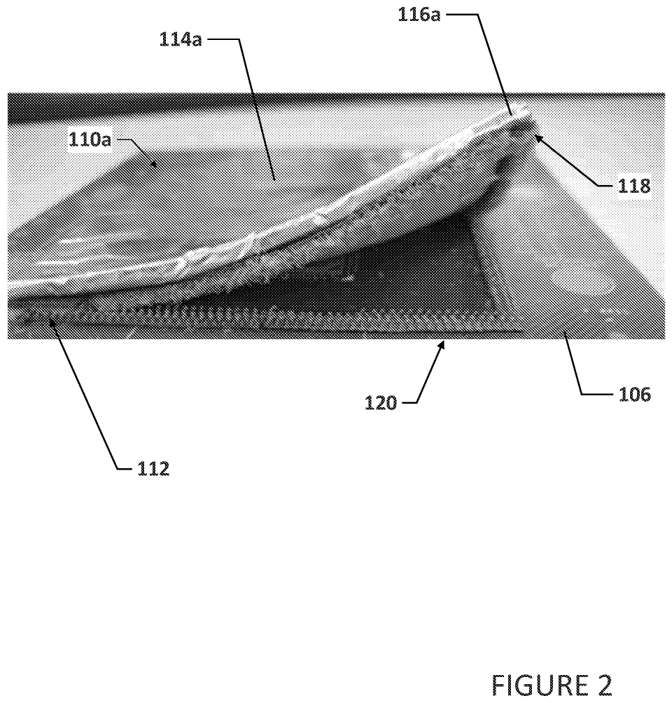

Turning to FIG. 2, FIG. 2 is a simplified diagram illustrating a radiation shield 110a attached to the support structure 106 using the hook and loop radiation shield securing mechanism 112, in accordance with an embodiment of the present disclosure. In an example, the radiation shield 110a is a flexible heat spreader. More specifically, the radiation shield 110a can include an elastic about two (2) mm thick thermal absorber sheet with about 0.05 mm aluminum sheet coating.

The loop portion 120 can be secured to the support structure 106 using a solder, adhesive, tape, a weld, a mechanical fastener (e.g., screw, bolt, rivet, etc.), or some other type of fastener or coupling means that can secure the loop portion 120 to the support structure 106. The hook portion 118 can be secured to the radiation shield wall portion 116a of the radiation shield 110a using a solder, adhesive, tape, a weld, a mechanical fastener (e.g., screw, bolt, rivet, etc.), or some other type of fastener or coupling means that can secure the hook portion 118 to the radiation shield wall portion 116a. The hook and loop radiation shield securing mechanism 112 can be coupled to the ground 122 so that the hook and loop radiation shield securing mechanism 112 and the radiation shield 110a. The lid portion 114 and the radiation shield wall portion 116 define a cavity inside the radiation shield 110a that can cover and house the one or more radiation sources 108 and can help provide a shielding mechanism for the one or more radiation sources 108.

The hook and loop radiation shield securing mechanism 112 can secure the radiation shield 110 to the support structure 106 without creating holes in support structure 106 or gaps between the radiation shield 110a and the support structure 106. In addition, the hook and loop radiation shield securing mechanism 112 can apply a low or almost zero vertical Z-load and about zero horizontal X-Y-loads to help prevent warpage and damage to the radiation shield 110a. Also, the hook and loop radiation shield securing mechanism 112 can be configured to provide a relatively low retention force to allow the radiation shield 110a to be removed from the support structure 106 without damaging the radiation shield 110a or the support structure 106.

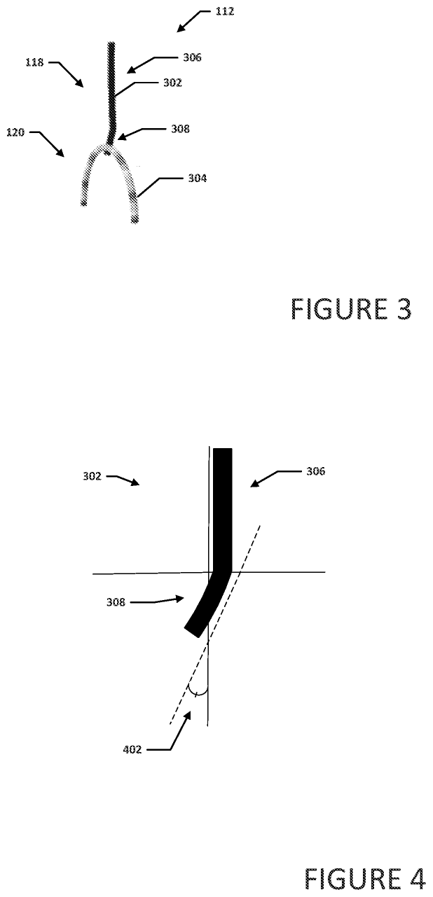

Turning to FIG. 3, FIG. 3 is a simplified block diagram of a portion of hook and loop radiation shield securing mechanism 112, in accordance with an embodiment of the present disclosure. The hook and loop radiation shield securing mechanism 112 can include the loop portion 120 and the hook portion 118. The hook portion 118 can include a plurality of hooks 302. The hooks can have a relatively straight body 306 and a retention hook 308. The loop portion 120 can include a plurality of loops 304. As illustrated in FIG. 3, the retention hook 308 can engage with the loop 304 and create a retention force that couples the hook portion 118 to the loop portion 120. As explained below with reference to FIGS. 4 and 5, the angle of the retention hook 308 is one of the major factors in determining the retention force (other than the number of hooks 302 and loops 304). It should be noted that not every hook 302 in the hook portion 118 must couple with a loop 304 in the loop portion 120 nor must every loop 304 in the loop portion 120 couple with a hook 302 in the hook portion 118 and intermittent matching can and most likely will occur, as is common with most hook and loop systems.

Turning to FIG. 4, FIG. 4 is a simplified block diagram of the hook 302, in accordance with an embodiment of the present disclosure. In an example, the hook includes the relatively straight body 306 and the retention hook 308. Other than the number of hooks 302 and loops 304, the angle of the retention hook 308 as compared to the relatively straight body 306 is the major factor in determining the retention force between the hook 302 and the loop 304. More specifically, as illustrated in FIG. 4, the retention hook 308 bends a hook angle 402 away from the relatively straight body 306. The greater the hook angle 402, the more the retention hook 308 bends away from the relatively straight body 306 and the greater the retention force between the hook 302 and the loop 304 when the hook 302 and loop 304 are coupled together, as illustrated in FIG. 3. The hook angle 402 can be equal to or less than about eighty degrees(80°) and ranges therein (e.g., less than about 65 degrees)(65°) , less than about thirty-five degrees)(35°), depending on design choice and design constrains. In some examples, the hook angle 402 can be equal to or less than about forty degrees (40°) and ranges therein (e.g., less than about thirty-five degrees)(35°), less than about twenty degrees(20°), depending on design choice and design constrains. For example, for a greater retention force and a larger applied load on a heat source, a larger hook angle 402 (e.g., about seventy degrees (70°)) can be used as opposed to smaller hook angle 402 (e.g., fifteen degrees (15°)) for a weaker retention force that is likely to not damage a flexible heat spreader when the flexible heat spreader is removed from the support structure.

Turning to FIG. 5, FIG. 5 is a simplified graph 500 illustrating examples details of how the hook geometry can affect the retention force of the hook and loop radiation shield securing mechanism 112, in accordance with an embodiment of the present disclosure. As illustrated in FIG. 5, as a hook angle (e.g., the hook angle 402 illustrated in FIG. 4) is increased, the retention force also increases. For example, at a hook angle of forty degrees (40°) and below, the retention force is below 100 millinewton (mN).

In an example, ranges of the hook angle can be used for different applications, depending on the desired retention forces. For example, for low retention force applications, an angle from a low retention range 502 can be used. The low retention range 502 can be a hook angle between about one degree (1°) and about forty degrees (40°) and ranges therein (e.g., between about five degrees (5°) to about twenty-five degrees (25°), or about ten degrees (10°) to about thirty degrees (30°), depending on design choice and design constraints. A hook angle in the low retention range 502 can be used for thin radiation shields that have a thickness of about 0.15 mm to about 0.2 mm where the radiation shield tends to bend relatively easily and a low retention force is required to prevent permeant deflection of the radiation shield or other damage to the radiation shield.

A moderate retention range 504 can be a hook angle between about forty degrees (40°) to about eighty degrees (80°) and ranges therein (e.g., between about fifty degrees (50°) to about seventy degrees (70°), or about forty-five degrees (45°) to about fifty-five degrees (55°)), depending on design choice and design constraints. A hook angle in the moderate retention range 504 can be used for relative stiff radiation shields, extended heat sinks, and cold plates that have a thickness of about 0.5 mm. The hook angle in the moderate retention range 504 can be used for applications where the radiation shield does not bend or does not easily bend and a retention force is required at the edges of the radiation shield. Also, the hook angle in the moderate retention range can be used to hold an applied load on the one or more radiation sources. In some examples, attachment screws can be used as the main locking and retention force and to help create an applied load on a heat source to help with the thermal transfer of heat away from the heat source. Above the moderate retention range 504, or a hook angle above about eighty degrees (80°) creates a high retention force that could damage the radiation shield and/or heat sink when the radiation shield and/or heat sink are removed from the support structure.

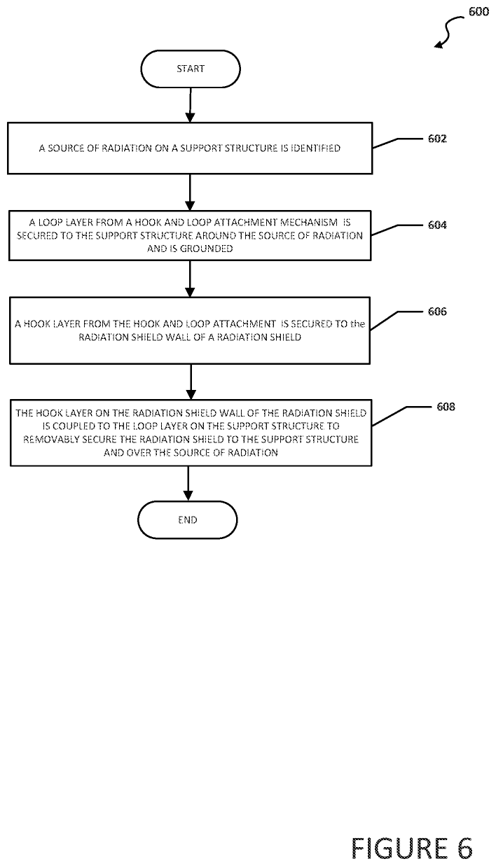

Turning to FIG. 6, FIG. 6 is an example flowchart illustrating possible operations of a flow 600 that may be associated with a hook and loop attachment for a radiation shield and a heat sink, in accordance with an embodiment. At 602, a source of radiation on a support structure is identified. For example, the radiation source 108 on the support structure 106 can be identified. At 604, a loop layer from a hook and loop attachment mechanism is secured to the support structure around the source of radiation and is grounded. For examples, the loop portion 120 of the hook and loop radiation shield securing mechanism 112 can be secured to the support structure 106 around the radiation source 108 and coupled to the ground 122. At 606, a hook layer from the hook and loop attachment structure is secured to the radiation shield wall of a radiation shield. For example, the hook portion 118 of the hook and loop radiation shield securing mechanism 112 can be secured to the radiation shield wall portion 116 of the radiation shield 110. At 608, the hook layer on the radiation shield wall of the radiation shield is coupled to the loop layer on the support structure to removably secure the radiation shield to the support structure and over the radiation source. For example, the hook portion 118 on the radiation shield wall portion 116 of the radiation shield 110 can be coupled to the loop portion 120 on the support structure 106 to removably secure the radiation shield 110 to the support structure 106 and over the radiation source 108.

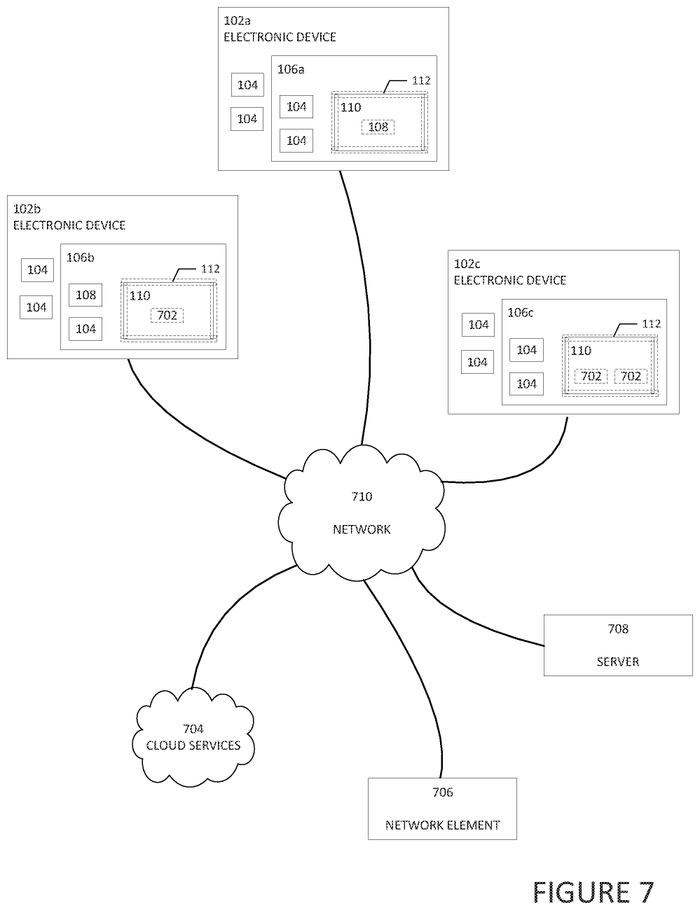

Turning to FIG. 7, FIG. 7 is a simplified block diagram of an electronic device configured with a hook and loop attachment for a radiation shield and a heat sink, in accordance with an embodiment of the present disclosure. For example, as illustrated in FIG. 7, an electronic device 102a includes the one or more electronics 104 and a support structure 106a. The support structure 106a can include at least one of the one or more electronics 104, the radiation source 108, the radiation shield 110, and the hook and loop radiation shield securing mechanism 112.

In an example, the support structure 106a can be a substrate and more particularly, a printed circuit board (PCB). The radiation source 108 can be on or over the support structure 106a and the radiation shield 110 can be over the radiation source 108 to help contain or mitigate the radiation from the radiation source 108 from extending past the radiation shield 110 or at least partially contain or mitigate the radiation from the radiation source 108 from extending past the radiation shield 110. The hook and loop radiation shield securing mechanism 112 can secure the radiation shield 110 to the support structure 106a without creating holes in support structure 106a.

In addition, an electronic device 102b can include one or more electronics 104 and a support structure 106b. The support structure 106b can include at least one of the one or more electronics 104, the one or more radiation sources 108, the radiation shield 110, the hook and loop radiation shield securing mechanism 112, and one or more radiation sensitive devices 702. In an example, the support structure 106b can be a substrate and more particularly, a printed circuit board (PCB).

The radiation shield 110 can be over the one or more radiation sensitive devices 702 to help shield the one or more radiation sensitive devices 702 from the radiation from the one or more radiation sources 108 or mitigate the effects of the radiation from the one or more radiation sources 108 from effecting the one or more radiation sensitive devices 702 or at least partially mitigate the effects of the radiation from the one or more radiation sources 108 on the one or more radiation sensitive devices 702. The hook and loop radiation shield securing mechanism 112 can secure the radiation shield 110 to the support structure 106b without creating holes in support structure 106b.

Also, an electronic device 102c includes one or more electronics 104 and a support structure 106c. The support structure 106c can include at least one of the one or more electronics 104, the radiation shield 110, hook and loop radiation shield securing mechanism 112, and the one or more radiation sensitive devices 702. In an example, the support structure 106c can be a substrate and more particularly, a printed circuit board (PCB).

The radiation shield 110 can be over the one or more radiation sensitive devices 702 to help shield the one or more radiation sensitive devices 702 from the radiation from outside of the electronic device 102c or mitigate the effects of the radiation from outside of the electronic device 102c from effecting the one or more radiation sensitive devices 702 or at least partially mitigate the effects of the radiation from outside of the electronic device 102c on the one or more radiation sensitive devices 702. The hook and loop radiation shield securing mechanism 112 can secure the radiation shield 110 to the support structure 106c without creating holes in support structure 106c.

Each of electronic devices 102a-102c (and electronic device 102) may be in communication with each other, cloud services 704, network element 706, and/or server 708 using network 710. In some examples, one or more of electronic devices 102a-102c (and electronic device 102) may be standalone devices and not connected to network 710 or another device.

Elements of FIG. 7 may be coupled to one another through one or more interfaces employing any suitable connections (wired or wireless), which provide viable pathways for network (e.g., network 710, etc.) communications. Additionally, any one or more of these elements of FIG. 7 may be combined or removed from the architecture based on particular configuration needs. Network 710 may include a configuration capable of transmission control protocol/Internet protocol (TCP/IP) communications for the transmission or reception of packets in a network. Each of electronic devices 102a-102c (and electronic device 102) may also operate in conjunction with a user datagram protocol/IP (UDP/IP) or any other suitable protocol where appropriate and based on particular needs.

Turning to the network infrastructure of FIG. 7, network 710 represents a series of points or nodes of interconnected communication paths for receiving and transmitting packets of information. Network 710 offers a communicative interface between nodes, and may be configured as any local area network (LAN), virtual local area network (VLAN), wide area network (WAN), wireless local area network (WLAN), metropolitan area network (MAN), Intranet, Extranet, virtual private network (VPN), and any other appropriate architecture or system that facilitates communications in a network environment, or any suitable combination thereof, including wired and/or wireless communication.

In network 710, network traffic, which is inclusive of packets, frames, signals, data, etc., can be sent and received according to any suitable communication messaging protocols. Suitable communication messaging protocols can include a multi-layered scheme such as Open Systems Interconnection (OSI) model, or any derivations or variants thereof (e.g., Transmission Control Protocol/Internet Protocol (TCP/IP), user datagram protocol/IP (UDP/IP)). Messages through the network could be made in accordance with various network protocols, (e.g., Ethernet, Infiniband, OmniPath, etc.). Additionally, radio signal communications over a cellular network may also be provided. Suitable interfaces and infrastructure may be provided to enable communication with the cellular network.

The term “packet” as used herein, refers to a unit of data that can be routed between a source node and a destination node on a packet switched network. A packet includes a source network address and a destination network address. These network addresses can be Internet Protocol (IP) addresses in a TCP/IP messaging protocol. The term “data” as used herein, refers to any type of binary, numeric, voice, video, textual, or script data, or any type of source or object code, or any other suitable information in any appropriate format that may be communicated from one point to another in electronic devices and/or networks.

In an example implementation, electronic devices 102 and 102a-102c are meant to encompass a computer, a personal digital assistant (PDA), a laptop or electronic notebook, a cellular telephone, a smartphone, an IP phone, Internet of Things device (IoT device) network elements, network appliances, servers, routers, switches, gateways, bridges, load balancers, processors, modules, or any other device, component, element, or object that includes a radiation source and/or a radiation sensitive device. Each of electronic devices 102 and 102a-102c may include any suitable hardware, software, components, modules, or objects that facilitate the operations thereof, as well as suitable interfaces for receiving, transmitting, and/or otherwise communicating data or information in a network environment. This may be inclusive of appropriate algorithms and communication protocols that allow for the effective exchange of data or information. Each of electronic devices 102 and 102a-102c may include virtual elements.

In regards to the internal structure, each of electronic devices 102 and 102a-102c can include memory elements for storing information to be used in operations. Each of electronic devices 102 and 102a-102c may keep information in any suitable memory element (e.g., random access memory (RAM), read-only memory (ROM), erasable programmable ROM (EPROM), electrically erasable programmable ROM (EEPROM), application specific integrated circuit (ASIC), etc.), software, hardware, firmware, or in any other suitable component, device, element, or object where appropriate and based on particular needs. Any of the memory items discussed herein should be construed as being encompassed within the broad term ‘memory element.’ Moreover, the information being used, tracked, sent, or received could be provided in any database, register, queue, table, cache, control list, or other storage structure, all of which can be referenced at any suitable timeframe. Any such storage options may also be included within the broad term ‘memory element’ as used herein.

In certain example implementations, functions may be implemented by logic encoded in one or more tangible media (e.g., embedded logic provided in an ASIC, digital signal processor (DSP) instructions, software (potentially inclusive of object code and source code) to be executed by a processor, or other similar machine, etc.), which may be inclusive of non-transitory computer-readable media. In some of these instances, memory elements can store data used for operations. This includes the memory elements being able to store software, logic, code, or processor instructions that are executed to carry out operations or activities.

Additionally, each of electronic devices 102 and 102a-102c can include one or more processors that can execute software or an algorithm. In one example, the processors could transform an element or an article (e.g., data) from one state or thing to another state or thing. In another example, activities may be implemented with fixed logic or programmable logic (e.g., software/computer instructions executed by a processor) and the elements identified herein could be some type of a programmable processor, programmable digital logic (e.g., a field programmable gate array (FPGA), an erasable programmable read-only memory (EPROM), an electrically erasable programmable read-only memory (EEPROM)) or an ASIC that includes digital logic, software, code, electronic instructions, or any suitable combination thereof. Any of the potential processing elements, modules, and machines described herein should be construed as being encompassed within the broad term ‘processor.’

Implementations of the embodiments disclosed herein may be formed or carried out on or over a substrate, such as a non-semiconductor substrate or a semiconductor substrate. In one implementation, the non-semiconductor substrate may be silicon dioxide, an inter-layer dielectric composed of silicon dioxide, silicon nitride, titanium oxide and other transition metal oxides. Although a few examples of materials from which the non-semiconducting substrate may be formed are described here, any material that may serve as a foundation upon which a non-semiconductor device may be built falls within the spirit and scope of the embodiments disclosed herein.

In another implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and molybdenum disulphide, organic materials such as pentacene, transparent oxides such as indium gallium zinc oxide poly/amorphous (low temperature of dep) III-V semiconductors and germanium/silicon, and other non-silicon flexible substrates. Although a few examples of materials from which the substrate may be formed are described here, any material that may serve as a foundation upon which a semiconductor device may be built falls within the spirit and scope of the embodiments disclosed herein.

Note that with the examples provided herein, interaction may be described in terms of one, two, three, or more elements. However, this has been done for purposes of clarity and example only. In certain cases, it may be easier to describe one or more of the functionalities by only referencing a limited number of elements. It should be appreciated that electronic devices 102 and 102a-102c and their teachings are readily scalable and can accommodate a large number of components, as well as more complicated/sophisticated arrangements and configurations. Accordingly, the examples provided should not limit the scope or inhibit the broad teachings of electronic devices 102 and 102a-102c and as potentially applied to a myriad of other architectures.

Although the present disclosure has been described in detail with reference to particular arrangements and configurations, these example configurations and arrangements may be changed significantly without departing from the scope of the present disclosure. For example, while the loop portion is shown as being secured to the support structure and the hook portion as being secured to the radiation shield wall portion of the radiation shield, the hook portion can be secured to the support structure and the loop portion can be secured to the radiation shield wall portion of the radiation shield. Moreover, certain components may be combined, separated, eliminated, or added based on particular needs and implementations. Additionally, although electronic devices 102 and 102a-102i have been illustrated with reference to particular elements and operations, these elements and operations may be replaced by any suitable architecture, protocols, and/or processes that achieve the intended functionality of electronic devices 102 and 102a-102i.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### OTHER NOTES AND EXAMPLES

In Example A1, an electronic device can include a support structure, a radiation source on the support structure, a radiation shield around the radiation source, and a hook and loop radiation shield securing mechanism to removably secure the radiation shield to the support structure. The hook and loop radiation shield securing mechanism can include a hook portion with a plurality of hooks and a loop portion that includes a plurality of loops, where an angle of a retention hook for each of the plurality of hooks is less than about eighty degrees.

In Example A2, the subject matter of Example A1 can optionally include where the angle of the retention hook for each of the plurality of hooks is less than about forty degrees.

In Example A3, the subject matter of Example A1 can optionally include where the hook and loop radiation shield securing mechanism is grounded to a ground plane of the support structure.

In Example A4, the subject matter of Example A1 can optionally include where the radiation shield is a flexible heat spreader.

In Example A5, the subject matter of Example A1 can optionally include where the radiation shield is a thermally conductive elastic material coated with a radiation shielding film.

In Example A6, the subject matter of Example A1 can optionally include where the radiation source is a heat source and the radiation shield is a grounded cold plate.

In Example A7, the subject matter of Example A1 can optionally include where the radiation source is a heat source and the radiation shield is a grounded vapor chamber.

In Example A8, the subject matter of Example A1 can optionally include where the loop portion is secured to the support structure and the hook portion is secured to a wall portion of the radiation shield.

In Example A9, the subject matter of Example A1 can optionally include where the support structure is a printed circuit board.

In Example A10, the subject matter of any one of Examples A1-A2 can optionally include where the hook and loop radiation shield securing mechanism is grounded to a ground plane of the support structure.

In Example A11, the subject matter of any one of Examples A1-A3 can optionally include where the radiation shield is a flexible heat spreader.

In Example A12, the subject matter of any one of Examples A1-A4 can optionally include where the radiation shield is a thermally conductive elastic material coated with a radiation shielding film.

In Example A13, the subject matter of any one of Examples A1-A5 can optionally include where the radiation source is a heat source and the radiation shield is a grounded cold plate.

In Example A14, the subject matter of any one of Examples A1-A6 can optionally include where the radiation source is a heat source and the radiation shield is a grounded vapor chamber.

In Example A15, the subject matter of any one of Examples A1-A7 can optionally include where the loop portion is secured to the support structure and the hook portion is secured to a wall portion of the radiation shield.

In Example A16, the subject matter of any one of Examples A1-A8 can optionally include where the support structure is a printed circuit board.

Example M1 is a method including identifying a radiation source on a support structure, attaching a loop layer to the support structure and around the radiation source, where the loop layer includes a plurality of loops, attaching a hook layer to a radiation shield, where the hook layer includes a plurality of hooks, where an angle of a retention hook for each of the plurality of hooks is less than about eighty degrees, and coupling the hook layer to the loop layer to removably secure the radiation shield over the radiation source.

In Example M2, the subject matter of Example M1 can optionally include where the angle of the retention hook for each of the plurality of hooks is less than about forty degrees.

In Example M, the subject matter of Example M1 can optionally include securing the loop layer to a ground plane of the support structure.

In Example M4, the subject matter of Example M1 can optionally include where the radiation shield is a flexible cold plate.

In Example M5, the subject matter of Example M1 can optionally include where the radiation shield is a thermally conductive elastic material coated with a radiation shielding film.

In Example, M6, the subject matter of Example M1 can optionally include where the support structure is a printed circuit board.

In Example, M7, the subject matter of Example M1 can optionally include where the radiation source emits electromagnetic interference (EMI) and/or radio-frequency interference (RFI).

In Example M8, the subject matter of any one of the Examples M1-M2 can optionally include securing the loop layer to a ground plane of the support structure.

In Example M9, the subject matter of any one of the Examples M1-M3 can optionally include where the radiation shield is a flexible cold plate.

In Example M10, the subject matter of any one of the Examples M1-M4 can optionally include where the radiation shield is a thermally conductive elastic material coated with a radiation shielding film.

In Example, M11, the subject matter of any one of the Examples M1-M5 can optionally include where the support structure is a printed circuit board.

In Example, M12, the subject matter of any one of the Examples M1-M6 can optionally include where the radiation source emits electromagnetic interference (EMI) and/or radio-frequency interference (RFI).

Example AA1 is a hook and loop radiation shield securing mechanism including a loop portion secured to a support structure and a hook portion secured to a radiation shield, where the hook portion includes a plurality of hooks and an angle of a retention hook for each of the plurality of hooks is less than about eighty degrees.

In Example AA2, the subject matter of Example AA1 can optionally include where the angle of the retention hook for each of the plurality of hooks is less than about forty degrees.

In Example AA3, the subject matter of Example AA1 can optionally include where the loop portion is grounded to a ground plane of the support structure.

In Example AA4, the subject matter of Example AA1 can optionally include where the hook and loop radiation shield securing mechanism is comprised of an electrically conductive material.

In Example AA5, the subject matter of any one of Examples AA1-AA2 can optionally include where the loop portion is grounded to a ground plane of the support structure.

In Example AA6, the subject matter of any one of Examples AA1-AA3 can optionally include where the hook and loop radiation shield securing mechanism is comprised of an electrically conductive material.

Example S1 is a system that includes means to identify a radiation source on a support structure, means to attach a loop layer to the support structure and around the radiation source, where the loop layer includes a plurality of loops, means to attach a hook layer to a radiation shield, where the hook layer includes a plurality of hooks, where an angle of a retention hook for each of the plurality of hooks is less than about eighty degrees, and means to couple the hook layer to the loop layer to removably secure the radiation shield over the radiation source.

In Example S2, the subject matter of Example S1 can optionally include where the angle of the retention hook for each of the plurality of hooks is less than about forty degrees.

In Example S3, the subject matter of Example S1 can optionally include means to secure the loop layer to a ground plane of the support structure.

In Example S4, the subject matter of Example S1 can optionally include where the radiation shield is a flexible cold plate.

In Example S5, the subject matter of Example S1 can optionally include where the radiation shield is a thermally conductive elastic material coated with a radiation shielding film.

In Example S6, the subject matter of Example S1 can optionally include where the support structure is a printed circuit board.

In Example S7, the subject matter of Example S1 can optionally include where the radiation source emits electromagnetic interference (EMI) and/or radio-frequency interference (RFI).

In Example S8, the subject matter of any one of the Examples S1-S2 can optionally include means to secure the loop layer to a ground plane of the support structure.

In Example S9, the subject matter of any one of the Examples S1-S3 can optionally include where the radiation shield is a flexible cold plate.

In Example S10, the subject matter of any one of the Examples S1-S4 can optionally include where the radiation shield is a thermally conductive elastic material coated with a radiation shielding film.

In Example S11, the subject matter of any one of the Examples S1-S5 can optionally include where the support structure is a printed circuit board.

In Example S12, the subject matter of any one of the Examples S1-S6 can optionally include where the radiation source emits electromagnetic interference (EMI) and/or radio-frequency interference (RFI).

Example X1 is a machine-readable storage medium including machine-readable instructions to implement a method or realize an apparatus as in any one of the Examples A1-A16, M1-M12, AA1-AA6, or S1-S12. Example Y1 is an apparatus comprising means for performing any of the Example methods M1-M12. In Example Y2, the subject matter of Example Y1 can optionally include the means for performing the method comprising a processor and a memory. In Example Y3, the subject matter of Example Y2 can optionally include the memory comprising machine-readable instructions.

What is claimed is:

1. An electronic device comprising:
a support structure;
a radiation source on the support structure;
a radiation shield around the radiation source; and
a hook and loop radiation shield securing mechanism to removably secure the radiation shield to the support structure, wherein the hook and loop radiation shield securing mechanism includes a hook portion with a plurality of hooks and a loop portion that includes a plurality of loops, wherein an angle of a retention hook for each of the plurality of hooks is less than about eighty degrees.

2. The electronic device of claim 1, wherein the angle of the retention hook for each of the plurality of hooks is less than about forty degrees.

3. The electronic device of claim 1, wherein the hook and loop radiation shield securing mechanism is grounded to a ground plane of the support structure.

4. The electronic device of claim 1, wherein the radiation shield is a flexible heat spreader.

5. The electronic device of claim 1, wherein the radiation shield is a thermally conductive elastic material coated with a radiation shielding film.

6. The electronic device of claim 1, wherein the radiation source is a heat source and the radiation shield is a grounded cold plate.

7. The electronic device of claim 1, wherein the radiation source is a heat source and the radiation shield is a grounded vapor chamber.

8. The electronic device of claim 1, wherein the loop portion is secured to the support structure and the hook portion is secured to a wall portion of the radiation shield.

9. The electronic device of claim 1, wherein the support structure is a printed circuit board.

10. A method comprising:
identifying a radiation source on a support structure;
attaching a loop layer to the support structure and around the radiation source, wherein the loop layer includes a plurality of loops;
attaching a hook layer to a radiation shield, wherein the hook layer includes a plurality of hooks, wherein an angle of a retention hook for each of the plurality of hooks is less than about eighty degrees; and
coupling the hook layer to the loop layer to removably secure the radiation shield over the radiation source.

11. The method of claim 10, wherein the angle of the retention hook for each of the plurality of hooks is less than about forty degrees.

12. The method of claim 10, further comprising:
securing the loop layer to a ground plane of the support structure.

13. The method of claim 10, wherein the radiation shield is a flexible cold plate.

14. The method of claim 10, wherein the radiation shield is a thermally conductive elastic material coated with a radiation shielding film.

15. The method of claim 10, wherein the support structure is a printed circuit board.

16. The method of claim 10, wherein the radiation source emits electromagnetic interference (EMI) and/or radio-frequency interference (RFI).

17. A hook and loop radiation shield securing mechanism comprising:
a loop portion secured to a support structure; and
a hook portion secured to a radiation shield, wherein the hook portion includes a plurality of hooks and an angle of a retention hook for each of the plurality of hooks is less than about eighty degrees.

18. The hook and loop radiation shield securing mechanism of claim 17, wherein the angle of the retention hook for each of the plurality of hooks is less than about forty degrees.

19. The hook and loop radiation shield securing mechanism of claim 17, wherein the loop portion is grounded to a ground plane of the support structure.

20. The hook and loop radiation shield securing mechanism of claim 17, wherein the hook and loop radiation shield securing mechanism is comprised of an electrically conductive material.
